(19) United States
(12) Patent Application Publication
(10) Pub. No.: US 2006/0145266 A1
(43) Pub. Date: Jul. 6, 2006

(54) Semiconductor integrated circuit

(75) Inventors: Hirofumi Zushi, Kodaira (JP); Kinya Mitsumoto, Tamamura (JP)

Correspondence Address: MILES & STOCKBRIDGE PC, 1751 PINNACLE DRIVE, SUITE 500, MCLEAN, VA, 22102-3833, US

(73) Assignee: Renesas Technology Corp.

(21) Appl. No.: 11/322,377

(22) Filed: Jan. 3, 2006

(30) Foreign Application Priority Data
Jan. 4, 2005 (JP) 2005-000090

(51) Int. Cl. H01L 29/94; H01L 29/76

(52) U.S. Cl. 257/369; 257/371; 257/368

(57) ABSTRACT

A semiconductor integrated circuit, whose MOS transistors' layout structure is determined in consideration of the size of a device active region in a gate length direction, in which each transistor is formed. When stresses coming from the device isolation region, etc. are taken into account, for a circuit whose current driving power reduction caused by the stresses should be suppressed, the distance between the device isolation regions in the gate length direction may be selected so as to suppress the reduction in drain-source current. Further, for a circuit whose logical threshold voltage variations caused by the stresses should be suppressed, the distance between the device isolation regions in the gate length direction may be selected so that the variations in drain-source current caused by such stresses are balanced between the p-channel and n-channel transistors. Characteristic variations arising in the transistors owing to stresses coming from the device isolation region, etc. are selectively used, whereby a desired performance required for the circuit is achieved readily.

### CLAIM OF PRIORITY

The Present application claims priority from Japanese application JP 2005-000090 filed on Jan. 4, 2005, the content of which is hereby incorporated by reference into this application.

### FIELD OF THE INVENTION

The present invention relates to a semiconductor integrated circuit having an insulated gate field effect transistor (which is also referred to as a MOS transistor simply) More specifically, it relates to a technique that is useful in application to a layout structure of a semiconductor device in consideration of variation in characteristics of the device under the condition where it is strained by a stress.

### BACKGROUND OF THE INVENTION

A MOS device, in which a thick field oxide film serves to separate elements, has been progressing to LOCOS type, and STI (Shallow Trench Isolation) type. In a CMOS process for which progress has been made in scaling down to a minimum fabrication size of e.g. 0.14 μm, STI structure is adopted for device isolation. In regard to CMOS devices manufactured according to such process, phenomena in which variations in e.g. the threshold voltage and current driving power of a MOS transistor arise are observed. A cause of the phenomena is considered to be a strain in a channel-forming region owing to a stress arising in a corner portion of a groove owing to the difference in the coefficient of thermal expansion between a substrate and a silicon oxide (SiO₂) film imbedded inside the groove of the STI structure. It can be considered that a strain in a channel-forming region caused by a stress resulting from the difference in the coefficient of thermal expansion is made larger and the phenomena are made more remarkable as the down-scaling of devices progresses. As for the phenomena, the following are reported in R. A. Bianchi, G. Bouche and O. Roux-dit-Buisson, “Accurate Modeling of Trench Isolation Induced Mechanical Stress Effection MOSFET Electrical Performance,” IEDM 2002, pp. 117-120, and Terence B. Hook, Serge Biesemanns and, James Slinkman, “The Dependence of Channel Length on Channel Width in Narrow-Channel CMOS Device for 0.35-0.13 um Technologies” IEEE Electron Device Lett. Vol. 21, No. 2, February 2000, pp. 85-87: changes in the mobility of electrons or holes in a channel region owing to the difference in the coefficient of thermal expansion between a silicon oxide film and a substrate; and the change in impurity profiles (change in the threshold voltage Vth). Further, it is described in JP-A-2002-368080 that the stress can be reduced by adjusting a separation width of a device isolation region such as STI.

Now, the MOS device characteristics resulting from the stress phenomenon shall be referred to as STI stress characteristics for the sake of convenience. Even when the MOS device characteristics are referred to as STI stress characteristics, their causes can be not only STI, but also e.g. a stress from a bottom side of a device in the case of a technique to perform device isolation from the bottom side of the device like e.g. SOI (Silicon On Insulator). The STI stress characteristics are to be reflected on MOS model parameters (BSIM4) that the Berkley presents, in which the width of an active region in a gate length direction is defined as a parameter LOD (Length gate Oxide Definition).

### SUMMARY OF THE INVENTION

The inventor examined not the conventional direction to reduce a stress owing to the STI, etc. from the point of view of the device structure, but utilization of the STI stress characteristics for the purpose of realizing a current driving power required for a circuit or a circuit performance such as the logical threshold voltage of the circuit. The main stress that a device active region accepts from a device isolation region is a stress in a compressing direction. Under such stress, the mobility of electrons is decreased, and reversely the mobility of holes is increased. Focusing such features, the inventor found it better, in regard to a circuit having different conductive types of devices therein such as a CMOS (Complementary Metal Oxide Semiconductor) circuit, to differentiate stresses owing to the STI, etc. that the MOS transistor accepts according to the conductive type of the MOS transistor or according to a current driving power required for the MOS transistor.

A representative object of the invention is to provide a semiconductor integrated circuit, for which a desired performance required for a circuit is achieved by selectively using variations in characteristics arising in a MOS transistor owing to a stress from a device isolation region, etc.

The above and other objects of the invention and the novel features thereof will be apparent from the description hereof and the accompanying drawings.

The outlines of representatives of the subject matters hereof disclosed herein will be briefly described below.

[1] As for a semiconductor integrated circuit, a layout structure of MOS transistors is determined in consideration of the size of a device active region, in which the MOS transistor is formed, in a gate length direction. In other words, the semiconductor integrated circuit has: plural kinds of p-channel MOS transistors formed in plural kinds of first device active regions respectively, the p-channel MOS transistors differing in a distance between device isolation regions thereof in a gate length direction; and n-channel MOS transistors formed in plural kinds of second device active regions respectively, the n-channel MOS transistors differing in a distance between device isolation regions in a gate length direction. Between the p-channel MOS transistors that are identical in gate width, a decrease in drain-source current owing to an influence of a stress on an active region is suppressed further with a reduction in the distance between the device isolation regions in the gate length direction. In addition, between the n-channel MOS transistors that are identical in gate width, a decrease in drain-source current owing to an influence of a stress on an active region is suppressed further with an increase in the distance between the device isolation regions in the gate length direction. The main stress that a device active region accepts from a device isolation region is a stress in a compressing direction. Under such stress, the mobility of electrons is decreased, and reversely the mobility of holes is increased. When the distance between the device isolation regions in the gate length direction is made larger, the influence of the stress can be relaxed or ignored.

Taking stresses that the active region accepts from the device isolation region, etc. into account based on the foregoing, for a circuit whose current driving power reduction caused by the stresses should be suppressed, the distance between the device isolation regions in the gate length direction may be selected so as to suppress the reduction in drain-source current. Further, taking stresses that the active region accepts from the device isolation region, etc. into account, for a circuit whose logical threshold voltage variations caused by the stresses should be suppressed, the distance between the device isolation regions in the gate length direction may be selected so that the variations in drain-source current caused by such stresses is balanced between the p-channel and n-channel MOS transistors. Variations in characteristics arising in the MOS transistor owing to stresses that the active region accepts from the device isolation region, etc. are selectively used in this way, whereby a desired performance required for the circuit is achieved.

As a representative form of the invention, the plural kinds of p-channel MOS transistors are arranged so as to differ in a distance from the device isolation region on a source side to a gate thereof, and so as to be identical in a distance from the device isolation region on a drain side to the gate. Thus, in the plural kinds of p-channel MOS transistors, the difference in distances between device isolation regions never causes the difference in parasitic capacitances of the drains and as such, the unwanted variation in load can be suppressed. In this case, the plural kinds of p-channel MOS transistors can flow a larger drain-source current with a reduction in the distance from the device isolation region on the source side to the gate.

As another representative form of the invention, the plural kinds of n-channel MOS transistors are arranged so as to differ in a distance from the device isolation region on a source side to a gate thereof, and so as to be identical in a distance from the device isolation region on a drain side to the gate. In this case, the plural kinds of n-channel MOS transistors can flow a larger drain-source current with an increase in the distance from the device isolation region on the source side to the gate.

[2] In regard to the semiconductor integrated circuit, by sharing a diffusion layer that makes a source or drain of a MOS transistor thereby to lengthen the device active region in the gate length direction, i.e. making larger the interval of placing the device isolation regions, it becomes possible to relax or ignore the influence of the stresses. Such sharing includes gate division and making a source shared by adjacent MOS transistors. In other words, the semiconductor integrated circuit includes: plural kinds of first device active regions in which p-channel MOS transistors are arrayed in parallel between device isolation regions in a gate length direction, wherein the adjacent p-channel MOS transistors arrayed in parallel in the respective first device active regions share a source or a drain, the p-channel MOS transistors formed in the first device active regions differing in their kinds respectively and each sharing the drain with the adjacent p-channel MOS transistor are arranged so as to be identical in a distance between gates sandwiching the drain, and the p-channel MOS transistors formed in the first device active regions differing in their kinds respectively and each sharing the source with the adjacent p-channel MOS transistor are arranged so as to be identical in a distance from the device isolation region on a drain side to the gate.

In the case of focusing on an n-channel MOS transistor, a semiconductor integrated circuit includes: plural kinds of second device active regions in which n-channel MOS transistors are arrayed in parallel between device isolation regions in a gate length direction, wherein the adjacent n-channel MOS transistors arrayed in parallel in the respective second device active regions share a source or a drain, the n-channel MOS transistors formed in the second device active regions differing in their kinds respectively and each sharing the drain with the adjacent n-channel MOS transistor are arranged so as to be identical in a distance between gates sandwiching the drain, and the n-channel MOS transistors formed in the second device active regions differing in their kinds respectively and each sharing the source with the adjacent n-channel MOS transistor are arranged so as to be identical in a distance from the device isolation region on a drain side to the gate.

[3] Now, attention will be directed toward a series circuit having CMOS inverters as a concrete example of a circuit in which a diffusion layer that makes a source or drain of a MOS transistor is shared. That is, a semiconductor integrated circuit includes: a series circuit having CMOS inverters, wherein p-channel MOS transistors constituting the series circuit are arrayed in parallel so as to share a first device active region between device isolation regions in a gate length direction, and the adjacent p-channel MOS transistors arrayed in parallel along the first device active region share a source or a drain, and n-channel MOS transistors constituting the series circuit are arrayed in parallel so as to share a second device active region between device isolation regions in a gate length direction, and the adjacent n-channel MOS transistors arrayed in parallel along the second device active region share a source or a drain.

From the foregoing, p-channel MOS transistors and n-channel MOS transistors that constitute a series circuit having CMOS inverters share diffusion layers each making a source or drain, whereby it becomes possible to ignore the influence of stresses from a device isolation region, etc. Therefore, as long as the series circuit having CMOS inverters is a delay circuit, the delay time is not influenced by such stresses. Further, a logical threshold voltage in the series circuit having CMOS inverters is not influenced by the stresses.

As a representative form of the invention, the first and second device active regions are identical in the length between the device isolation regions in the gate length direction with each other.

[4] As another concrete example of a circuit in which a diffusion layer that makes a source or drain of a MOS transistor is shared, attention will be directed toward a series circuit having CMOS inverters used as a driver. That is, a semiconductor integrated circuit includes: a series circuit having CMOS inverters, wherein p-channel MOS transistors constituting the series circuit are formed in specific first device active regions respectively and arrayed in parallel, and n-channel MOS transistors constituting the series circuit are arrayed in parallel so as to share a second device active region between device isolation regions in a gate length direction, and the adjacent n-channel MOS transistors arrayed in parallel along the second device active region share a source or a drain.

From the foregoing, the p-channel MOS transistors are formed in the different device active regions respectively, and the distance between the device isolation regions in the gate length direction is made smaller, whereas in the n-channel MOS transistors, the distance between the device isolation regions in the gate length direction is enlarged by sharing a source or drain. Thus, the current driving power according to the CMOS inverter is enhanced as a whole.

As a representative form of the invention, a length of the first device active region in the gate length direction of the p-channel MOS transistor is shorter than a length of the second device active region in the gate length direction of the n-channel MOS transistor.

### BRIEF DESCRIPTION OF THE DRAWINGS

FIG. 1 is an illustration showing an embodiment of an n-channel MOS transistor, to which the invention is applied, exemplarily showing representative layout arrangements and drain-source current (Ids) characteristics of the MOS transistor;

FIG. 2 is an illustration showing an embodiment of a p-channel MOS transistor, to which the invention is applied, exemplarily showing representative layout arrangements and drain-source current (Ids) characteristics of the MOS transistor;

FIG. 3 is an illustration exemplarily showing conditions of varying Ids with respect to LOD sizes;

FIG. 4 is a sectional view exemplarily showing a sectional structure of the MOS transistor for which a monocrystalline silicon substrate is used;

FIG. 5 is an illustration showing the definition of LOD;

FIG. 6 is a sectional view exemplarily showing a sectional structure of the MOS transistor for which an SOI substrate is used;

FIG. 7 is a plan view showing an example of a layout arrangement to relax the influence of the stress form STI on a series circuit of CMOS inverters;

FIG. 8 is a plan view showing a layout as an example for comparison with the layout shown in FIG. 7;

FIG. 9 is a plan view showing another example of a layout arrangement to selectively use the influence of the stress from STI thereby to enhance the driving power of a driver;

FIG. 10 is a plan view showing a layout as an example for comparison with the layout shown in FIG. 9;

FIG. 11 is a block showing an SRAM as an example of a semiconductor integrated circuit having an elemental circuit to which the MOS transistor shown in FIG. 7 or 9 is applied; and

FIG. 12 is a plan view exemplarily showing a geometric arrangement of circuit blocks that constitute the SRAM shown in FIG. 11.

### DETAILED DESCRIPTION OF THE PREFERRED EMBODIMENTS

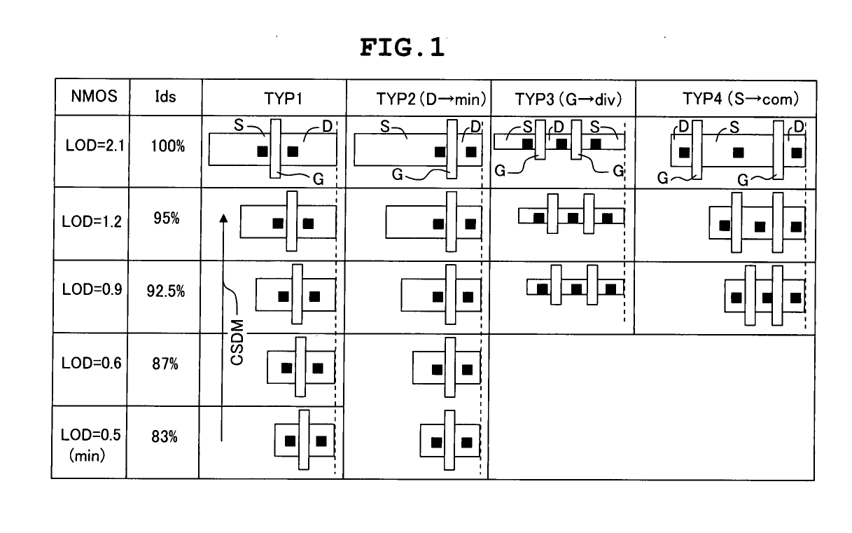

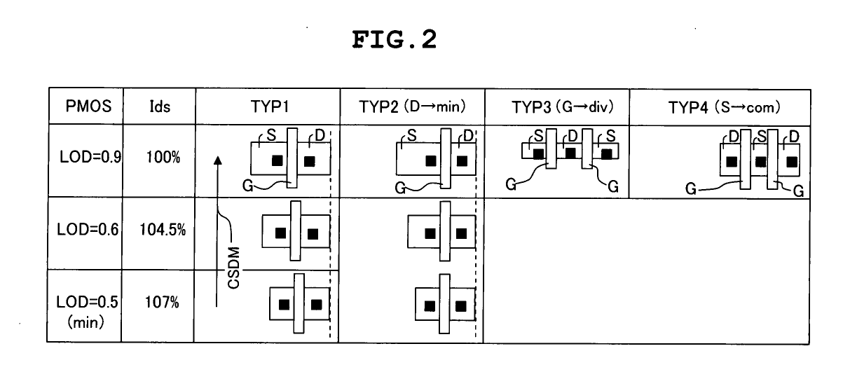

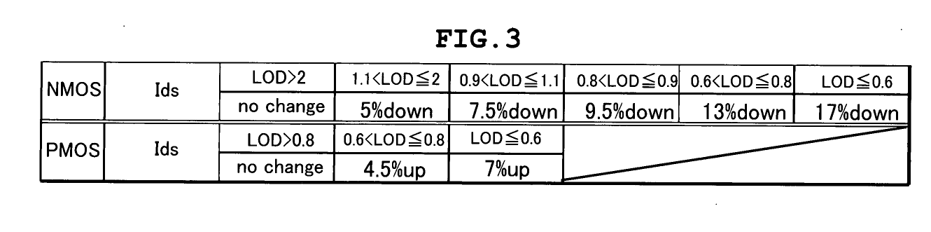

Referring to FIG. 1, there are shown an embodiment of an n-channel MOS transistor (NMOS), to which the invention is applied, exemplarily showing representative layout arrangements and drain-source current (Ids) characteristics of the MOS transistor. FIG. 2 shows an embodiment of a p-channel MOS transistor (PMOS), to which the invention is applied, exemplarily showing representative layout arrangements and drain-source current (Ids) characteristics of the MOS transistor. FIG. 3 shows conditions of varying Ids with respect to the LOD sizes.

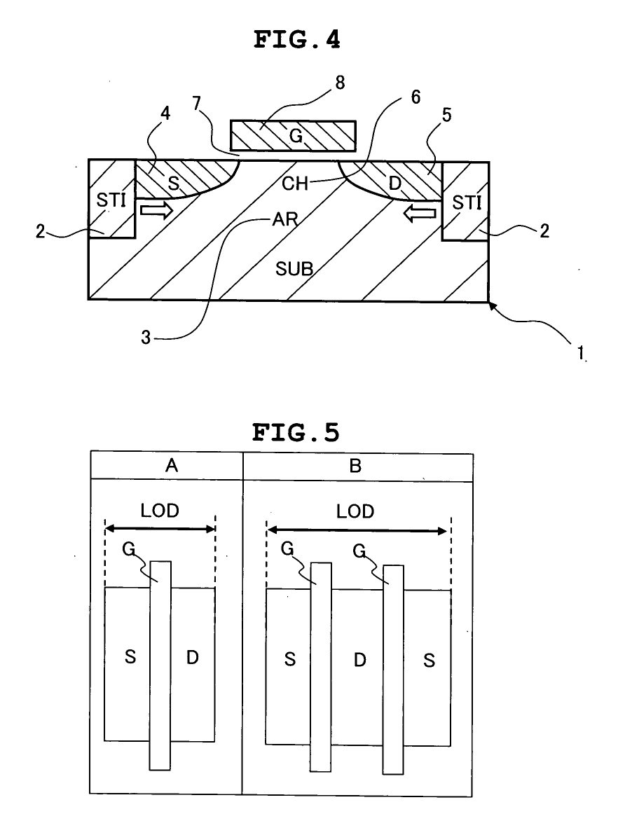

Here is assumed e.g. a MOS transistor having a sectional structure as shown in FIG. 4. The MOS transistor shown in the drawing is formed on a substrate 1. The substrate 1 is a substrate (SUB) made of a semiconductor such as monocrystalline silicon here. Reference numeral 2 represents an STI that is an example of device isolation region. The numeral 3 represents a device active region (AR) that is a semiconductor region surrounded by the STI 2. The numeral 4 represents a source (S). The numeral 5 represents a drain (D). A gate (G) 8 is formed over a channel-forming region 6 between the source 4 and drain 5 through a gate oxide film 7. The difference in coefficient of thermal expansion between the device active region 3 and device isolation region 2 causes a stress in a compressing direction to act on the device active region 3 from the device isolation region 2. When the stress acts on a channel of the MOS transistor, the mobility of electrons is decreased, whereas the mobility of holes is increased. In other words, in the case of a p-channel MOS transistor, such stress works in a direction such that the source-drain current Ids is increased. In contrast, in the case of an n-channel MOS transistor, such stress works in a direction such that the source-drain current Ids is decreased.

It has become clear that the influence of such stress is changed depending on the distance between device isolation regions in a gate length direction. The distance can be expressed by a parameter, LOD (Length gate Oxide Definition) LOD is defined as shown in FIG. 5. In other words, LOD may be considered as the sum of the length of a source diffusion layer, the length of a drain diffusion layer and the gate length in the gate length direction. This is common in both the case where one MOS transistor is formed on a device active region as shown in Column A of FIG. 5, and the case where two MOS transistors sharing one drain D are formed on a device active region as shown in Column B of FIG. 5.

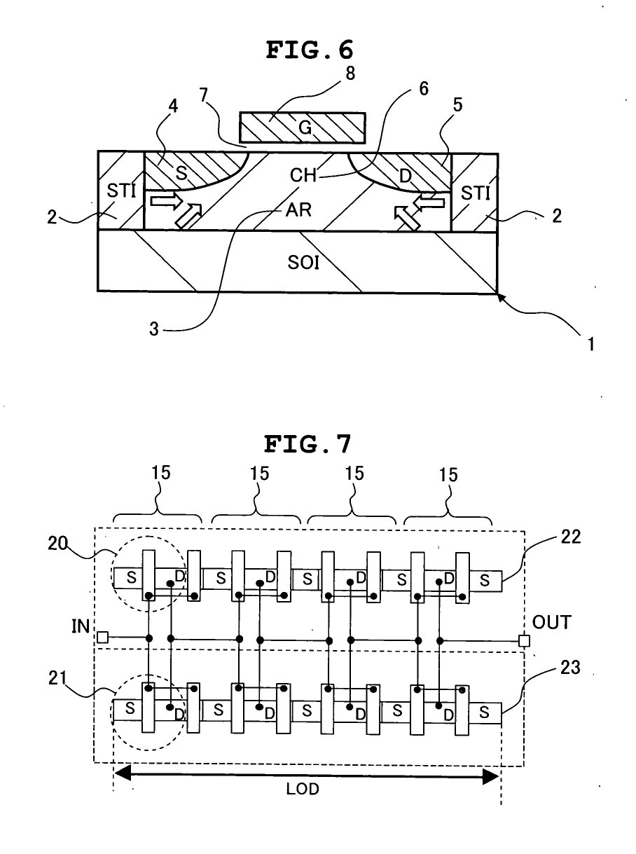

As for the sectional structure, an SOI substrate structure may be adopted as a substrate 1 as shown in FIG. 6. When the SOI structure is adopted, it is expected that the device active region 3 also receives a stress in a compressing direction from the SOI substrate. The influence of the stress is considered to be larger than that in the case of FIG. 4.

Now, referring to FIG. 1, wherein Ids performances are shown using the length of LOD (in micrometers) as a parameter. The Ids performance is the result of the circuit simulation. In the case of an n-channel MOS transistor, the smaller the LOD is made, the worse the current characteristic Ids becomes. This is because the mobility of electrons in the channel is made smaller with an increase in stress from the device isolation region. As shown in FIG. 3, in the case where LOD is more than 2 μm, there is no change in Ids characteristic. As for the size of the MOS transistor, the better the Ids characteristic is, the larger the size of the transistor becomes. The orientation of the arrow CSDM represents that of the disadvantage in association with the transistor size. Four kinds of layout forms of the MOS transistor are shown.

In the first layout form TYP1, the source S and drain D are made identical in the size of the diffusion layer. The minimum fabrication size is obtained when LOD=0.5 μm.

In the second layout form TYP2, the size of the diffusion layer of the drain D is constant, regardless of the size of LOD. Here, the minimum fabrication size is adopted (D->min), and the size of the diffusion layer of the source S is changed depending on the value of LOD. In the second layout form TYP2, the drain capacity is made smaller regardless of the size of LOD in comparison to the first layout form TYP1. When the second layout form is used for a CMOS inverter, etc., the following are made possible. The first is to suppress an increase in parasitic capacitance that will be an unwanted output load. The second is to prevent the parasitic capacitance that will be an unwanted output load from being changed depending on the LOD size.

The third layout form TYP3 shows the case where the gate division has been performed (D->div), in which separated left and right n-channel MOS transistors share a drain D. Also, in the third layout form TYP3, the size of the drain diffusion layer is constant regardless of the LOD size. In this case, the distance between the gates is made the minimum fabrication size.

The fourth layout form TYP4 presents a layout when a source S is used in common between adjacent MOS transistors (S->com). Also, in the fourth layout form TYP4, the size of the drain diffusion layer is constant regardless of the LOD size. Therefore, the size of the diffusion layer of the source S must be changed depending on the LOD size. However, keeping a good balance with the minimum fabrication size in connection with the distance between gates, it is impossible to form a pattern smaller than LOD=0.9 μm, here.

Now, referring to FIG. 2, wherein Ids performances are shown using the length of LOD (in micrometers) as a parameter. The Ids performance is the result of the circuit simulation. The larger the LOD is made, the worse the current characteristic Ids becomes. This is because the mobility of holes in the channel is made larger with an increase in stress from the device isolation region in the case of a p-channel MOS transistor. As shown in FIG. 3, in the case where LOD is more than 0.8 μm, there is no change in Ids characteristic. As for the size of the MOS transistor, the worse the Ids characteristic is, the larger the size of the transistor becomes. The orientation of the arrow CSDM represents that of the disadvantage in association with the transistor size. Four kinds of layout forms of the MOS transistor are shown.

In the first layout form TYP1, the source S and drain D are made identical in the size of the diffusion layer. The minimum fabrication size is obtained when LOD=0.5 μm.

In the second layout form TYP2, the size of the diffusion layer of the drain D is constant, regardless of the size of LOD. Here, the minimum fabrication size is adopted (D->min), and the size of the diffusion layer of the source S is changed depending on the value of LOD. In the second layout form TYP2, the drain capacity is made smaller regardless of the size of LOD in comparison to the first layout form TYP1. When the second layout form is used for a CMOS inverter, etc., the following are made possible. The first is to suppress an increase in parasitic capacitance that will be an unwanted output load. The second is to prevent the parasitic capacitance that will be an unwanted output load from being changed depending on the LOD size.

The third layout form TYP3 shows the case where the gate division has been performed (D->div), in which separated left and right p-channel MOS transistors share a drain D. Also, in the third layout form TYP3, the size of the drain diffusion layer is constant regardless of the LOD size, which is not particularly shown in the drawing. In this case, the distance between the gates is made the minimum fabrication size.

The fourth layout form TYP4 presents a layout when a source S is used in common between adjacent MOS transistors (S->com) Also, in the fourth layout form TYP4, the size of the drain diffusion layer is constant regardless of the LOD size, which is not particularly shown in the drawing. Therefore, the size of the diffusion layer of the source S must be changed depending on the LOD size. However, keeping a good balance with the minimum fabrication size in connection with the distance between gates, it is impossible to form a pattern smaller than LOD=0.9 mm, here.

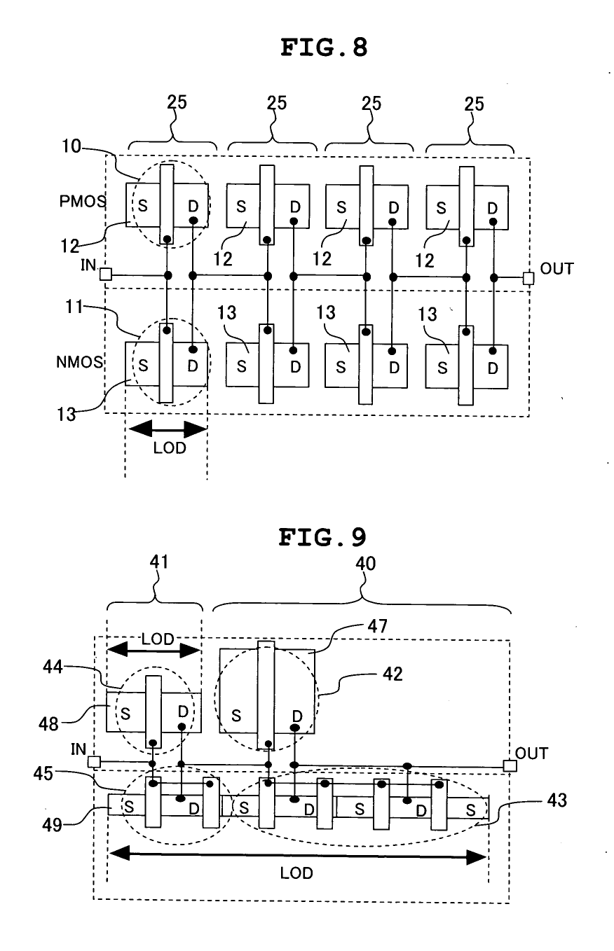

Referring to FIG. 7, there is shown an example of a layout arrangement to relax the influence of a stress from a device isolation region STI on a series circuit of CMOS inverters 25. Prior to the description with reference to FIG. 7, a layout as a comparative example thereto will be described with reference to FIG. 8. In FIG. 8, a p-channel MOS transistor 10 and an n-channel MOS transistor 11 of a CMOS inverter 15 are formed in the specific device active regions 12 and 13, respectively. For example, the n-channel MOS transistor may be formed under the condition of LOD=0.9 μm shown in FIG. 1, and the p-channel MOS transistor may be formed under the condition of LOD=0.9 μm shown in FIG. 2. In this case, Ids of the p-channel MOS transistor 10 is 100%, and Ids of the n-channel MOS transistor 11 is reduced to 92.5%.

In the example shown in FIG. 7, the third forms TYP3 shown in FIGS. 1, 2 are applied, in which eight p-channel MOS transistors 20 are formed in one n-type device active region 22, and eight n-channel MOS transistors 21 are formed in one p-type device active region 23. LOD of the device active region 22 in which the p-channel MOS transistors 20 are formed is 0.9 μm or larger. LOD of the device active region 23 in which the n-channel MOS transistors 21 are formed is 2.1 μm or larger. Hence, Ids of the p-channel MOS transistors 20 and Ids of the n-channel MOS transistors 21 are 100%, and therefore it becomes possible to substantially ignore the influence of the stress. Thus, the logical threshold voltage of each CMOS inverter 25 is never changed under the influence of the stress from STI. In addition, the signal propagation delay time produced by the series circuit of the CMOS inverters 25 is never changed under the influence of the stress from STI. The circuit shown in FIG. 7 may be utilized as a delay circuit, for example. It is the drivability of each delay stage that counts in regard to a delay circuit. Therefore, an arrangement such that both the p-channel MOS transistors 20 and n-channel MOS transistors 21 are not changed in their current characteristics under the influence of the stress from STI as shown in FIG. 7 is suitable for a delay circuit. Also, in regard to an output circuit, the arrangement shown in FIG. 7 is the most suitable from the viewpoint of output impedance.

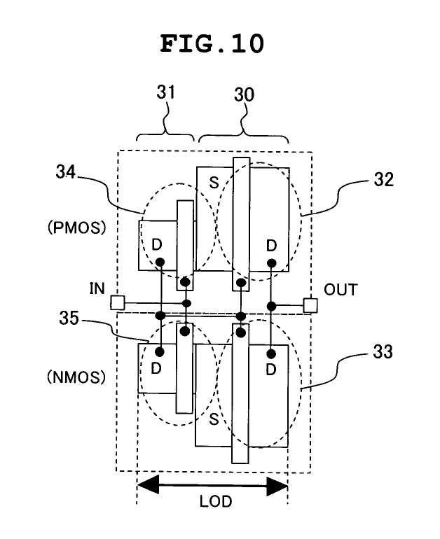

Referring to FIG. 9, there is exemplarily shown a layout arrangement to selectively use the influence of the stress from STI thereby to enhance the driving power of a driver. Prior to the description with reference to FIG. 9, a layout as a comparative example thereto will be described with reference to FIG. 10. In FIG. 10, an output stage CMOS inverter 30 and a preceding stage CMOS inverter 31 are connected in series. The CMOS inverter 30 includes a p-channel MOS transistor 32 and an n-channel MOS transistor 33. The CMOS inverter 31 includes a p-channel MOS transistor 34 and an n-channel MOS transistor 35. As for the CMOS inverter 30, large gate widths are set to ensure a required driving power in the p-channel MOS transistor 32 and n-channel MOS transistor 33. The CMOS inverters 30, 31 share a source diffusion layer. The device active regions of the p-channel and n-channel MOS transistors are identical in size to each other.

The layout arrangement shown in FIG. 9 differs from that shown in FIG. 10 in its driving power is enhanced. In FIG. 9, an output stage CMOS inverter 40 and a preceding stage CMOS inverter 41 are connected in series. The CMOS inverter 40 includes a p-channel MOS transistor 42 and an n-channel MOS transistor 43. The CMOS inverter 41 includes a p-channel MOS transistor 44 and an n-channel MOS transistor 45. As for the p-channel MOS transistors 42, 44, the device active regions 47, 48 are provided separately on an individual transistor basis for the purpose of increasing the current Ids. Incidentally, the gate width is not changed. As for the n-channel MOS transistors 43, 45, for the purpose of enabling the influence of the stress to be ignored, the source and drain are shared between adjacent MOS transistors to enlarge LOD of the device active region 49. In short, it is taken into account concerning the n-channel MOS transistors 43, 45 to suppress a decrease in Ids owing to the stress, and it is taken into consideration concerning the p-channel MOS transistors 42, 44 to make good use of the influence of the stress thereby to increase Ids. Now, in the arrangement shown in FIG. 9, LOD of the device active region 49 is enlarged in comparison to the arrangement shown in FIG. 10, and then the cell size in the gate length direction is made larger by the amount of the enlargement of LOD, but the size in the gate width direction is reduced.

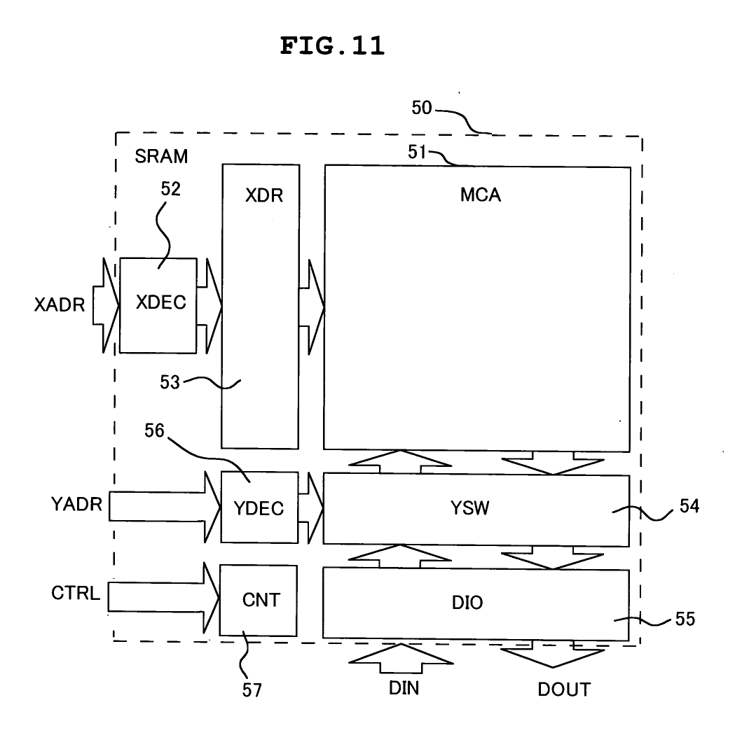

Referring to FIG. 11, there is shown an SRAM as an example of a semiconductor integrated circuit to which the above-described MOS transistor is applied. The SRAM 50 shown in the drawing has a memory cell array (MCA) 51 in which many static memory cells are arrayed in a matrix. Selective terminals of the memory cells are connected to word lines on an individual row basis, and bit transition connections are established with data input/output terminals of the memory cells on an individual column basis. Which word line should be selected is designated by a column address signal XADR. The address decoder (XDEC) 52 decodes the column address signal XADR. The word driver (XDR) 53 drives the word line selected according to the result of the decoding to its selective level. The bit line that is selected by the column-selecting switch circuit (YSW) 54 is brought into conduction with the data input/output circuit (DIO) 55. The selecting operation by the column-selecting switch circuit 54 is performed according to the result of decoding by the column decoder (YDEC) 56 that decodes a column address signal YADR. The data input/output circuit 55 has: a sense amplifier that senses data read out from the selected memory cell; a data output buffer that outputs the data amplified by the sense amplifier to the outside; and a data input buffer to which data written from the outside is input. The control circuit (CNT) 57 accepts an access control signal CTRL, and produces internal control signals for data input and output operations by the data input/output circuit 55, activation of the decoders 52, 56, and the like. For the circuits that constitute the SRAM 50, adopted is the above-described arrangement by which the Ids characteristic variations that the MOS transistor undergoes owing to the stress from the device isolation region can be used selectively according to a desired circuit characteristic. For example, the arrangement shown in FIG. 9 may be adopted for clock driver that controls for speed performance, a data output buffer and a word driver. In addition, for a logical stage of a decoder, the arrangement shown in FIG. 7 may be adopted for the purpose of suppressing variation of the logical threshold voltage of a CMOS circuit.

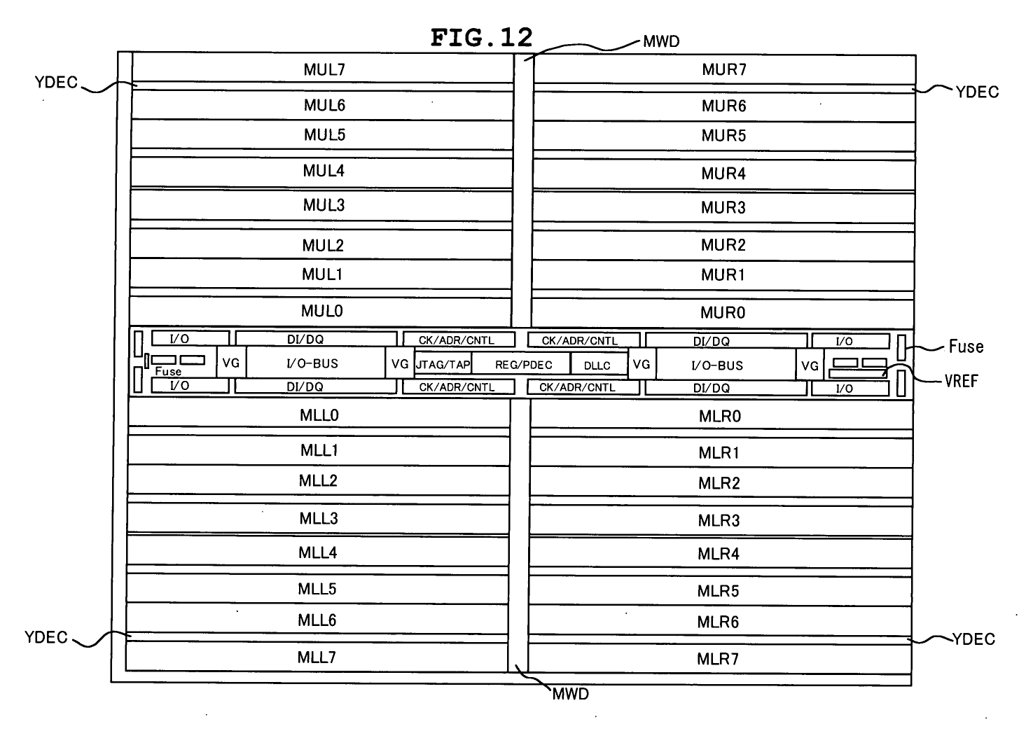

Referring to FIG. 12, there is exemplarily shown a geometric arrangement of circuit blocks that constitute the SRAM. MUL0-MUL7, MUR0-MUR7, MLL0-MLL7, and MLR0-MLR7 constitute the memory cell array 51. MWD is a main word driver. CK/ADR/CNTL is an input circuit for a clock signal, an address signal, a memory control signal, etc. DI/DQ is a data input/output circuit. I/O is an input/output circuit for a mode switching signal, a test signal, a DC signal, etc. Here is adopted a center pad system to array external connection terminals. Therefore, the CK/ADR/CNTL circuit, DI/DQ circuit and I/O circuit are located in a center portion of the chip. In addition, REG/PDEC is a predecoder or the like. DLLC is a clock synchronization circuit. JTAG/TAP is a test circuit. VG is an internal source voltage generator circuit. Further, Fuse is a fuse circuit, which is used to give relief of a defect in the memory array, and for the other purpose. VREF generates a reference voltage to acquire an input signal or the like. The main word driver MWD corresponds to XDR 53. REG/PDEC corresponds to XDEC 52. The input circuit CK/ADR/CNTL, input/output circuit I/O, synchronization circuit DLLC, test circuit JTAG/TAP, internal source voltage generator circuit VG, fuse circuit Fuse, and the generator circuit VREF for generating a reference voltage or the like are included in the CNT 57. The data input/output circuit DI/DQ corresponds to the data input/output circuit DIO 55.

The delay circuit, which has been described with reference to FIG. 7, may be applied to the clock synchronization circuit DLLC. Also, the driver circuit, which has been described with reference to FIG. 9, may be applied to the main word driver MWD.

With the above-described semiconductor integrated circuit, the following effects and advantages can be obtained. (1) According to the layout arrangement adopted hereby, the length of the diffusion layer in the gate length direction, in which a source and a drain of a MOS transistor are formed, or the length of the device active region between the device isolation regions in the gate length direction is shortened or lengthened depending on the required Ids characteristic. In short, variations in characteristic in the MOS transistor owing to the stress produced by the device isolation region or the like is used selectively. Thus, it becomes possible to achieve a semiconductor integrated circuit for which a desired performance necessary for the circuit is realized from the viewpoint of Ids characteristics. (2) Particularly, use of a layout arrangement by which the width of a diffusion layer on the side of a drain of a MOS transistor, i.e. the distance from the device isolation region on the side of the drain to the gate in the gate length direction is shorter than the distance from the device isolation region on the side of the source to the gate, allows the parasitic capacitance of the drain to be made constant regardless of the difference in length between the active regions. Therefore, the layout arrangement is suitable to suppress variations of the output impedance or output driving power of a CMOS circuit. (3) By making source and drain diffusion layers shared by adjacent MOS transistors, the number of device isolation regions provided in the devices can be reduced. Therefore, the stress from the device isolation region can be avoided readily. (4) A layout arrangement such that good use is made of stress characteristics can be achieved by shortening the length of a device active region in the gate length direction in regard to a p-channel MOS transistor and making source and drain diffusion layers shared by adjacent transistors thereby to lengthen the length of the device active region in the gate length direction in regard to an n-channel MOS transistor, according to the required performance of an elemental circuit of a semiconductor integrated circuit.

While the invention made by the inventor has been described based on the embodiments specifically, it is not limited so. It is needless to say that various modifications and changes may be made without departing from the subject matters hereof.

For example, the elemental circuit that selectively uses stress characteristics of a MOS transistor is not limited by the above description, and it may be applied to an appropriate circuit. Also, the semiconductor integrated circuit is not limited to an SRAM. It may be widely applied to other memories including a DRAM, a mask ROM, an EEPROM and a flash memory, semiconductor integrated circuits for data processing including a microprocessor and an accelerator for image processing, etc. Further, the semiconductor integrated circuits are not limited to those using a monocrystal line silicon substrate. Also, the invention may be applied to a semiconductor integrated circuit using an SOI substrate or the like.

What is claimed is:

1. A semiconductor integrated circuit comprising:
plural kinds of p-channel MOS transistors formed in plural kinds of first device active regions respectively, the p-channel MOS transistors differing in a distance between device isolation regions thereof in a gate length direction; and
plural kinds of n-channel MOS transistors formed in plural kinds of second device active regions respectively, the n-channel MOS transistors differing in a distance between device isolation regions in a gate length direction,
wherein between the p-channel MOS transistors that are identical in gate width, of the plural kinds of p-channel MOS transistors, a decrease in drain-source current owing to an influence of a stress on an active region is suppressed further with a reduction in the distance between the device isolation regions in the gate length direction, and
wherein between the n-channel MOS transistors that are identical in gate width, of the plural kinds of n-channel MOS transistors, a decrease in drain-source current owing to an influence of a stress on an active region is suppressed further with an increase in the distance between the device isolation regions in the gate length direction.

2. The semiconductor integrated circuit of claim 1, wherein the plural kinds of p-channel MOS transistors are arranged so as to differ in a distance from the device isolation region on a source side to a gate thereof, and so as to be identical in a distance from the device isolation region on a drain side to the gate.

3. The semiconductor integrated circuit of claim 2, wherein the plural kinds of p-channel MOS transistors can flow a larger drain-source current with a reduction in the distance from the device isolation region on the source side to the gate.

4. The semiconductor integrated circuit of claim 1, wherein the plural kinds of n-channel MOS transistors are arranged so as to differ in a distance from the device isolation region on a source side to a gate thereof, and so as to be identical in a distance from the device isolation region on a drain side to the gate.

5. The semiconductor integrated circuit of claim 4, wherein the plural kinds of n-channel MOS transistors can flow a larger drain-source current with an increase in the distance from the device isolation region on the source side to the gate.

6. A semiconductor integrated circuit comprising:
plural kinds of first device active regions in which p-channel MOS transistors are arrayed in parallel between device isolation regions in a gate length direction,
wherein the adjacent p-channel MOS transistors arrayed in parallel in the respective first device active regions share a source or a drain,
wherein the p-channel MOS transistors formed in the first device active regions differing in their kinds respectively and each sharing the drain with the adjacent p-channel MOS transistor are arranged so as to be identical in a distance between gates sandwiching the drain, and
wherein the p-channel MOS transistors formed in the first device active regions differing in their kinds respectively and each sharing the source with the adjacent p-channel MOS transistor are arranged so as to be identical in a distance from the device isolation region on a drain side to the gate.

7. A semiconductor integrated circuit comprising:
plural kinds of second device active regions in which n-channel MOS transistors are arrayed in parallel between device isolation regions in a gate length direction,
wherein the adjacent n-channel MOS transistors arrayed in parallel in the respective second device active regions share a source or a drain,
wherein the n-channel MOS transistors formed in the second device active regions differing in their kinds respectively and each sharing the drain with the adjacent n-channel MOS transistor are arranged so as to be identical in a distance between gates sandwiching the drain, and
wherein the n-channel MOS transistors formed in the second device active regions differing in their kinds respectively and each sharing the source with the adjacent n-channel MOS transistor are arranged so as to be identical in a distance from the device isolation region on a drain side to the gate.

8. A semiconductor integrated circuit comprising:
a series circuit including CMOS inverters,
wherein p-channel MOS transistors constituting the series circuit are arrayed in parallel so as to share a first device active region between device isolation regions in a gate length direction, and the adjacent p-channel MOS transistors arrayed in parallel along the first device active region share a source or a drain, and
wherein n-channel MOS transistors constituting the series circuit are arrayed in parallel so as to share a second device active region between device isolation regions in a gate length direction, and the adjacent n-channel MOS transistors arrayed in parallel along the second device active region share a source or a drain.

9. The semiconductor integrated circuit of claim 8, wherein the first and second device active regions are identical in the length between the device isolation regions in the gate length direction with each other.

10. A semiconductor integrated circuit comprising:
a series circuit including CMOS inverters,
wherein plurality of p-channel MOS transistors constituting the series circuit are formed in specific first device active regions respectively and arrayed in parallel, and
wherein plurality of n-channel MOS transistors constituting the series circuit are arrayed in parallel so as to share a second device active region between device isolation regions in a gate length direction, and the adjacent n-channel MOS transistors arrayed in parallel along the second device active region share a source or a drain.

11. The semiconductor integrated circuit of claim 10, wherein a length of the first device active region in the gate length direction of the p-channel MOS transistor is shorter than a length of the second device active region in the gate length direction of the n-channel MOS transistor.
